(19) United States
(12) Patent Application Publication
(10) Pub. No.: US 2013/0023079 A1
(43) Pub. Date: Jan. 24, 2013

(54) FABRICATION OF LIGHT EMITTING DIODES (LEDS) USING A DEGAS PROCESS

(71) Applicants: Sang Won Kang, San Jose, CA (US); Jiang Lu, Milpitas, CA (US); Hua Chung, San Jose, CA (US); Juno Yu-Ting Huang, Santa Clara, CA (US); Wei-Yung Hsu, San Jose, CA (US)

(72) Inventors: Sang Won Kang, San Jose, CA (US); Jiang Lu, Milpitas, CA (US); Hua Chung, San Jose, CA (US); Juno Yu-Ting Huang, Santa Clara, CA (US); Wei-Yung Hsu, San Jose, CA (US)

(21) Appl. No.: 13/552,344

(22) Filed: Jul. 18, 2012

Related U.S. Application Data
(60) Provisional application No. 61/509,812, filed on Jul. 20, 2011.

(51) Int. Cl. H01L 33/04

(52) U.S. Cl. 438/46; 257/E33.008

(57) ABSTRACT

Methods of fabricating light emitting diodes using a degas process are described. For example, a method includes providing a partially formed group III-V material layer stack of an LED. Contaminants are removed from the partially formed group III-V material layer stack by a degas process. Formation of the group III-V material layer stack of the LED is then completed.

### CROSS-REFERENCE TO RELATED APPLICATIONS

This application claims the benefit of U.S. Provisional Application No. 61/509,812, filed Jul. 20, 2011, the entire contents of which are hereby incorporated by reference herein.

### BACKGROUND

1) Field

Embodiments of the present invention pertain to the field of group III-V materials and, in particular, to the fabrication of light emitting diodes using a degas process.

2) Description of Related Art

Group III-V materials are playing an ever increasing role in the semiconductor and related, e.g. light-emitting diode (LED), industries. Often, group III-V materials are difficult to grow or deposit without the formation of defects or cracks. For example, high quality surface preservation of select films, e.g. a gallium nitride film, is not straightforward in many applications using stacks of material layers fabricated sequentially.

### SUMMARY

Embodiments of the present invention include methods of fabricating light emitting diodes using a degas process.

In an embodiment, a method of fabricating a light emitting diode (LED) includes providing a partially formed group III-V material layer stack of an LED. Contaminants are removed from the partially formed group III-V material layer stack by a degas process. Formation of the group III-V material layer stack of the LED is then completed.

In another embodiment, a method of fabricating a light emitting diode (LED) includes providing a substrate having an n-GaN layer disposed there above. A MQW is formed above the n-GaN layer. The MQW includes a plurality of bottom barrier layer and top well layer pairs. The bottom barrier layer of the first of the plurality of pairs is formed on the n-GaN layer under degas conditions different from the conditions used to form the barrier layers of the other pairs of the plurality of pairs.

In another embodiment, a method of fabricating an LED includes providing a substrate having an n-type gallium nitride (n-GaN) layer disposed there above in a chamber having a first condition. The condition of the chamber is altered to a second condition different from the first condition to remove, by a degas process, contaminants from the n-GaN layer. A multiple quantum well (MQW) is formed above the n-GaN layer. The MQW includes a plurality of bottom barrier layer and top well layer pairs. The bottom barrier layer of the first of the plurality of pairs formed on the n-GaN layer is formed under a third condition of the chamber. The third condition has a difference from the second condition greater than the difference from the first condition.

### BRIEF DESCRIPTION OF THE DRAWINGS

FIG. 1 includes a photoluminescence (PL) plot for material stacks formed without use of a degas process, a plot of standard deviation across the material stacks, and a plot of mean peak intensity across the material stacks.

FIG. 2 includes the PL plot from FIG. 1 compared against a PL plot for III-V material stacks formed with the use of a degas process, in accordance with an embodiment of the present invention.

FIG. 3 is a Flowchart representing operations in a method of fabricating an LED, in accordance with an embodiment of the present invention.

FIG. 4 is a schematic cross-sectional view of an MOCVD chamber suitable for use in fabricating a portion of an LED in conjunction with a degas process, in accordance with an embodiment of the present invention.

FIG. 5 illustrates a system suitable for use in fabricating a portion of an LED in conjunction with a degas process, in accordance with an embodiment of the present invention.

FIG. 6 illustrates a cross-sectional view of a gallium nitride (GaN)-based light-emitting diode (LED), in accordance with an embodiment of the present invention.

FIG. 7 illustrates a cluster tool schematic, an LED structure, and a time-to-deposition plot, in accordance with one or more embodiments of the present invention.

### DETAILED DESCRIPTION

Methods of fabricating light emitting diodes (LEDs) using a degas process are described. In the following description, numerous specific details are set forth, such as MOCVD chamber configurations and material regimes, in order to provide a thorough understanding of embodiments of the present invention. It will be apparent to one skilled in the art that embodiments of the present invention may be practiced without these specific details. In other instances, well-known features, such as tool layouts or specific diode configurations, are not described in detail in order to not unnecessarily obscure embodiments of the present invention. Furthermore, it is to be understood that the various embodiments shown in the Figures are illustrative representations and are not necessarily drawn to scale. Additionally, other arrangements and configurations may not be explicitly disclosed in embodiments herein, but are still considered to be within the spirit and scope of the invention.

Photoluminescence (PL) is a significant factor used to determine the quality of a fabricated LED. Typically, the greater the PL from an LED, the more valuable the LED for end-users. Improvements in the fabrication of LEDs are often targeted to increasing the PL of LEDs or increasing the number of LEDs with a high PL that may be produced on a given substrate. In accordance with embodiments of the present invention, one or more degas processes are used during the manufacturing of a III-V material stack in order to increase the yield of good PL LEDs producible from a single substrate. In an example, the uniformity of brightness (based on optical power and photoluminescence intensity) of LEDs produced from a single wafer is improved.

In one or more embodiments described herein, issues with non-uniformity in brightness of LEDs are mitigated or eliminated by adding one or more degas operations immediately before or during fabrication of a multiple quantum well feature of an LED. In such embodiments, impurities may be removed from the product wafer itself, from a carrier used to support the product wafer, or from dummy wafers also situated on such a carrier. One or more of several degas operations may be considered, such as but not limited to, increasing temperature for several minutes before or during MQW fabrication, lowering pressure prior to MQW growth, or increasing growth temperature for prior to first well growth of the MQW. Such degas operations may be used to improve brightness uniformity. In a specific embodiment, photoluminescence intensity is improved from 30% standard deviation to 10% standard deviation across a single substrate used for manufacturing LEDs.

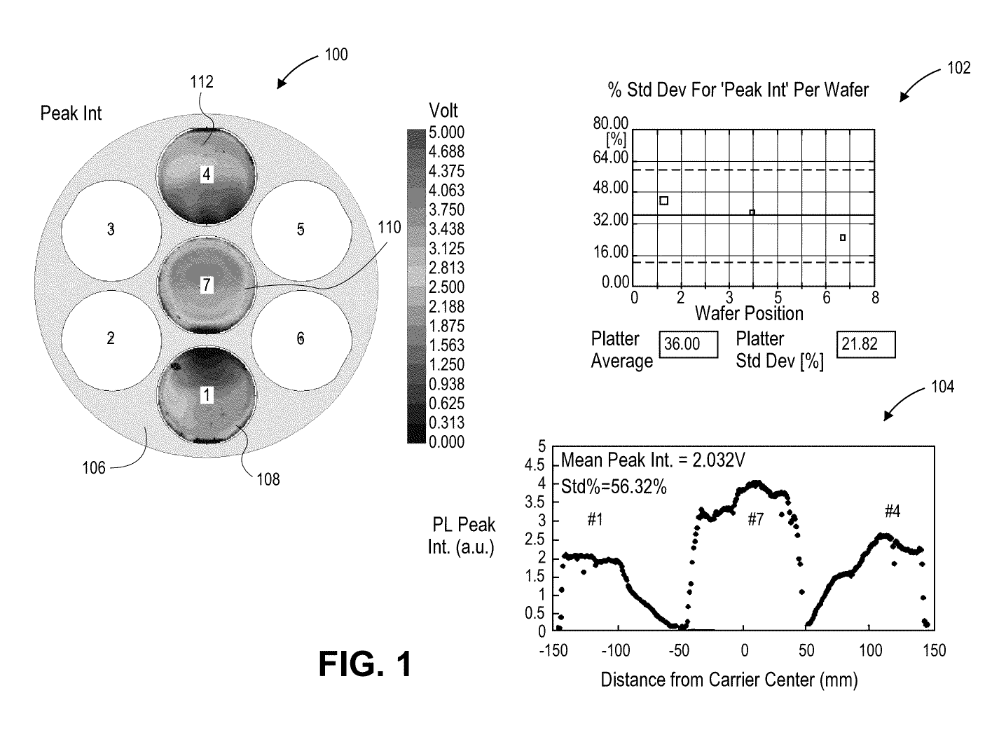

FIG. 1 includes a photoluminescence (PL) plot 100 for III-V material stacks formed without use of a degas process, a plot 102 of standard deviation across the III-V material stacks, and a plot 104 of mean peak intensity across the III-V material stacks. Referring to FIG. 1, a carrier 106 holds three substrates 108, 110, and 112 each having III-V material stacks formed thereon. The portions of the III-V material stacks of substrates 108 and 112 facing into the carrier 106 are the dimmest of all the III-V material stacks. The PL data indicated with shading in plot 100 is consistent with the standard deviation across the III-V material stacks and the mean peak intensity of plots 102 and 104, respectively. The issue of poor across-wafer uniformity demonstrated in FIG. 1 may be exacerbated if there is an air break in a manufacturing process used between forming an MQW on an underlying III-V-nitride layer or if the underlying III-V-nitride layer is provided pre-fabricated on a substrate, as described in more detail below.

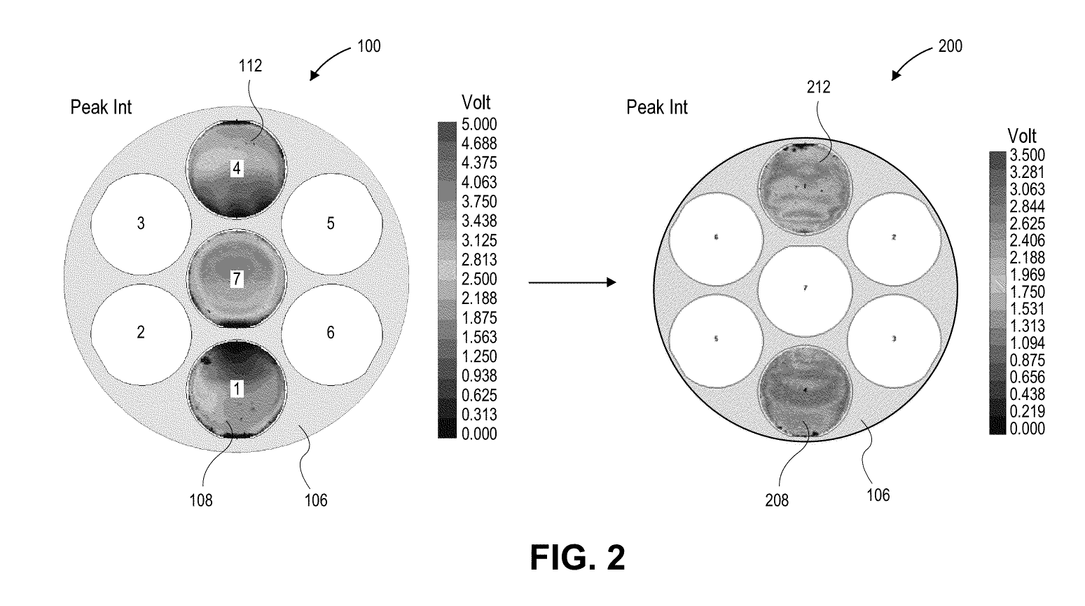

FIG. 2 includes PL plot 100 from FIG. 1 compared against a PL plot 200 for III-V material stacks formed with the use of a degas process, in accordance with an embodiment of the present invention. Referring to FIG. 2, in plot 200, the carrier 106 holds two new substrates 208 and 212 each having III-V material stacks formed thereon. The PL intensity measured for portions of the III-V material stacks of substrates 208 and 212 facing into the carrier are significantly improved as compared with the measurements for substrates 108 and 112. Furthermore, the overall across-wafer uniformity is improved. Thus, issues with non-uniform brightness may be addressed adding degas operations into the LED manufacturing process, particular during manufacture of a III-V material stack. In an embodiment, degas operations, such as degas operations described in greater detail below are used to remove possible impurities from the wafer carrier, from dummy wafers, or from the product wafers. Impurities may include chlorine-containing species resulting from a cleaning chlorine treatment of a deposition chamber.

In an embodiment, the duration for each of the degas operations described below is approximately in the range of 1-5 minutes. A degas operation may be performed prior to loading a substrate in a deposition chamber loading and/or, possibly, after cleaning the deposition chamber. A degas operation may also be performed after loading a substrate in a deposition chamber. In an embodiment, a degas operation is performed in same chamber used to deposit layers of an MQW structure of an LED device.

LEDs and related devices may be fabricated from layers of, e.g., group III-V films, especially group III-nitride films. Some embodiments of the present invention relate to forming gallium nitride (GaN) layers in a dedicated chamber of a fabrication tool, such as in a dedicated metal-organic chemical vapor deposition (MOCVD) chamber. In some embodiments of the present invention, GaN is a binary GaN film, but in other embodiments, GaN is a ternary film (e.g., InGaN, AlGaN) or is a quaternary film (e.g., InAlGaN). In at least some embodiments, the group III-nitride material layers are formed epitaxially. They may be formed directly on a substrate or on a buffers layer disposed on a substrate.

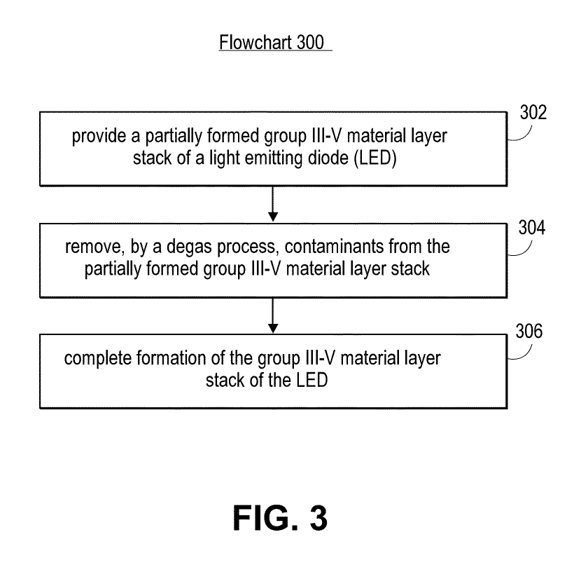

In an aspect of the present invention, a degas process is used to increase the PL output of a III-V material layer stack used to fabricate a plurality of LEDs. For example, FIG. 3 is a Flowchart 300 representing operations in a method of fabricating an LED, in accordance with an embodiment of the present invention.

As an example of a portion of a III-V material-based LED contemplated for illustrative purposes herein, e.g. with respect to Flowchart 300, FIG. 6 illustrates a cross-sectional view of a gallium nitride (GaN)-based LED, in accordance with an embodiment of the present invention. Referring to FIG. 6, a GaN-based LED 600 includes an n-type GaN template 604 (e.g., n-type GaN, n-type InGaN, n-type AlGaN, n-type InAlGaN) on a substrate 602 (e.g., planar sapphire substrate, patterned sapphire substrate (PSS), silicon substrate, silicon carbide substrate). The GaN-based LED 600 also includes a multiple quantum well (MQW), or active region, structure or film stack 606 on or above the n-type GaN template 604 (e.g., an MQW composed of one or a plurality of field pairs of InGaN well/GaN barrier material layers 608, as depicted in FIG. 6). The GaN-based LED 600 also includes a p-type GaN (p-GaN) layer or film stack 610 on or above the MQW 606, and a metal contact or ITO layer 612 on the p-GaN layer.

Referring to operation 302 of Flowchart 300, a method of fabricating an LED includes providing a partially formed group III-V material layer stack of the LED.

In an embodiment, providing the partially formed group III-V material layer stack of the LED includes providing an n-type gallium nitride (n-GaN) layer above a substrate. Completing formation of the group III-V material layer stack of the LED includes forming an MQW above the n-GaN layer. In one such embodiment, providing the n-GaN layer above the substrate includes forming the n-GaN layer in the same process tool used to form the MQW. That is, the MQW may be formed subsequent to formation of the n-GaN layer without removing the substrate from the process tool between forming the n-GaN layer and the MQW. In another such embodiment, providing the n-GaN layer above the substrate includes introducing the n-GaN layer and substrate pairing into a process tool for forming the MQW. For example, a fabrication process may start with forming an MQW on an n-GaN layer/substrate pairing that has been supplied by a vendor in that form. In another example, a deposition process is interrupted by introducing the n-GaN layer/substrate pairing at the time of MQW fabrication.

Referring to operation 304 of Flowchart 300, the method further includes removing, by a degas process, contaminants from the partially formed group III-V material layer stack.

In an embodiment, removing, by the degas process, contaminants from the partially formed group III-V material layer stack further includes removing contaminants from a carrier used to support a substrate having the partially formed group III-V material layer stack disposed there above. In an embodiment, removing, by the degas process, contaminants from the partially formed group III-V material layer stack enhances the photoluminescence (PL) of a finally fabricated LED based there from.

Referring to operation 306 of Flowchart 300, the method further includes completing formation of the group III-V material layer stack of the LED. For example, additional layers such as those described in association with FIG. 6 may be formed on or above the MQW.

In a more specific embodiment, degas conditions are used in the fabrication of an n-GaN based LED. In a first example, a method of fabricating an LED includes providing a substrate having an n-GaN layer disposed there above. A MQW is formed above the n-GaN layer. The MQW includes a plurality of bottom barrier layer and top well layer pairs. The bottom barrier layer of the first of the plurality of pairs is formed on the n-GaN layer under degas conditions different from the conditions used to form the barrier layers of the other pairs of the plurality of pairs.

In one such embodiment, at least a portion of the bottom barrier layer of the first of the plurality of pairs is formed at a temperature approximately in the range of 1000-1200 degrees Celsius. The barrier layers of the other pairs of the plurality of pairs are formed at a temperature of approximately 850 degrees Celsius. In a specific such embodiment, the entire bottom barrier layer of the first of the plurality of pairs is formed at a temperature approximately in the range of 1000-1200 degrees Celsius.

In a second example, a method of fabricating an LED includes providing a substrate having an n-type gallium nitride (n-GaN) layer disposed there above in a chamber having a first condition. The condition of the chamber is altered to a second condition different from the first condition to remove, by a degas process, contaminants from the n-GaN layer. A multiple quantum well (MQW) is formed above the n-GaN layer. The MQW includes a plurality of bottom barrier layer and top well layer pairs. The bottom barrier layer of the first of the plurality of pairs formed on the n-GaN layer is formed under a third condition of the chamber. The third condition has a difference from the second condition greater than the difference from the first condition.

In one such embodiment, the condition is temperature. The first condition is a temperature of approximately 300 degrees Celsius, the second condition is a temperature approximately in the range of 1000-1200 degrees Celsius, and the third condition is a temperature of approximately 850 degrees Celsius. In another such embodiment, the condition is pressure. The first condition is a pressure of approximately 70 Torr, the second condition is a pressure less than 70 Torr, and the third condition is a pressure of approximately 100 Torr.

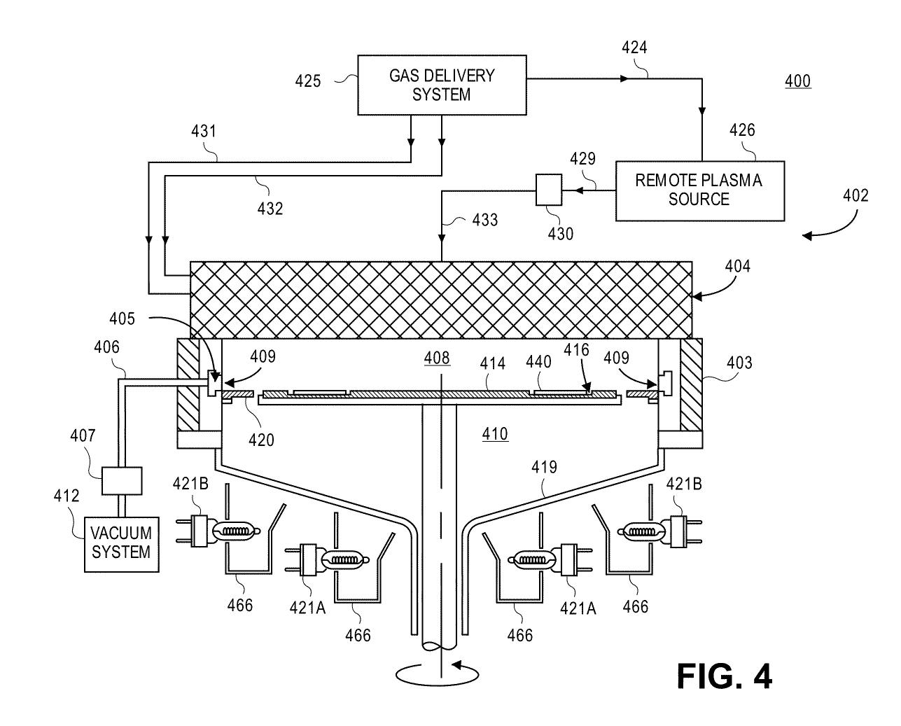

An example of a metal organic chemical vapor deposition (MOCVD) deposition chamber suitable for use in fabricating a portion of an LED in conjunction with a degas process, in accordance with embodiments of the present invention, is illustrated and described with respect to FIG. 4. FIG. 4 is a schematic cross-sectional view of an MOCVD chamber.

The apparatus 400 shown in FIG. 4 includes a chamber 402, a gas delivery system 425, a remote plasma source 426, and a vacuum system 412. The chamber 402 includes a chamber body 403 that encloses a processing volume 408. A showerhead assembly 404 is disposed at one end of the processing volume 408, and a substrate carrier 414 is disposed at the other end of the processing volume 408. A lower dome 419 is disposed at one end of a lower volume 410, and the substrate carrier 414 is disposed at the other end of the lower volume 410. The substrate carrier 414 is shown in process position, but may be moved to a lower position where, for example, the substrates 440 may be loaded or unloaded. An exhaust ring 420 may be disposed around the periphery of the substrate carrier 414 to help prevent deposition from occurring in the lower volume 410 and also help direct exhaust gases from the chamber 402 to exhaust ports 409. The lower dome 419 may be made of transparent material, such as high-purity quartz, to allow light to pass through for radiant heating of the substrates 440. The radiant heating may be provided by a plurality of inner lamps 421A and outer lamps 421B disposed below the lower dome 419, and reflectors 466 may be used to help control chamber 402 exposure to the radiant energy provided by inner and outer lamps 421A, 421B. Additional rings of lamps may also be used for finer temperature control of the substrate 440.

The substrate carrier 414 may include one or more recesses 416 within which one or more substrates 440 may be disposed during processing. The substrate carrier 414 may carry six or more substrates 440. In one embodiment, the substrate carrier 414 carries eight substrates 440. It is to be understood that more or less substrates 440 may be carried on the substrate carrier 414. Typical substrates 440 may include sapphire, silicon carbide (SiC), silicon, or gallium nitride (GaN). It is to be understood that other types of substrates 440, such as glass substrates 440, may be processed. Substrate 440 size may range from 50 mm-100 mm in diameter or larger. The substrate carrier 414 size may range from 200 mm-750 mm. The substrate carrier 414 may be formed from a variety of materials, including SiC or SiC-coated graphite. It is to be understood that substrates 440 of other sizes may be processed within the chamber 402 and according to the processes described herein. The showerhead assembly 404 may allow for more uniform deposition across a greater number of substrates 440 and/or larger substrates 440 than in traditional MOCVD chambers, thereby increasing throughput and reducing processing cost per substrate 440.

The substrate carrier 414 may rotate about an axis during processing. In one embodiment, the substrate carrier 414 may be rotated at about 2 RPM to about 100 RPM. In another embodiment, the substrate carrier 414 may be rotated at about 30 RPM. Rotating the substrate carrier 414 aids in providing uniform heating of the substrates 440 and uniform exposure of the processing gases to each substrate 440.

The plurality of inner and outer lamps 421A, 421B may be arranged in concentric circles or zones (not shown), and each lamp zone may be separately powered. In one embodiment, one or more temperature sensors, such as pyrometers (not shown), may be disposed within the showerhead assembly 404 to measure substrate 440 and substrate carrier 414 temperatures, and the temperature data may be sent to a controller (not shown) which can adjust power to separate lamp zones to maintain a predetermined temperature profile across the substrate carrier 414. In another embodiment, the power to separate lamp zones may be adjusted to compensate for precursor flow or precursor concentration non-uniformity. For example, if the precursor concentration is lower in a substrate carrier 414 region near an outer lamp zone, the power to the outer lamp zone may be adjusted to help compensate for the precursor depletion in this region.

The inner and outer lamps 421A, 421B may heat the substrates 440 to a temperature of about 400 degrees Celsius to about 1200 degrees Celsius. It is to be understood that the invention is not restricted to the use of arrays of inner and outer lamps 421A, 421B. Any suitable heating source may be utilized to ensure that the proper temperature is adequately applied to the chamber 402 and substrates 440 therein. For example, in another embodiment, the heating source may include resistive heating elements (not shown) which are in thermal contact with the substrate carrier 414.

A gas delivery system 425 may include multiple gas sources, or, depending on the process being run, some of the sources may be liquid sources rather than gases, in which case the gas delivery system may include a liquid injection system or other means (e.g., a bubbler) to vaporize the liquid. The vapor may then be mixed with a carrier gas prior to delivery to the chamber 402. Different gases, such as precursor gases, carrier gases, purge gases, cleaning/etching gases or others may be supplied from the gas delivery system 425 to separate supply lines 431, 432, and 433 to the showerhead assembly 404. The supply lines 431, 432, and 433 may include shut-off valves and mass flow controllers or other types of controllers to monitor and regulate or shut off the flow of gas in each line.

A conduit 429 may receive cleaning/etching gases from a remote plasma source 426. The remote plasma source 426 may receive gases from the gas delivery system 425 via supply line 424, and a valve 430 may be disposed between the showerhead assembly 404 and remote plasma source 426. The valve 430 may be opened to allow a cleaning and/or etching gas or plasma to flow into the showerhead assembly 404 via supply line 433 which may be adapted to function as a conduit for a plasma. In another embodiment, apparatus 400 may not include remote plasma source 426 and cleaning/etching gases may be delivered from gas delivery system 425 for non-plasma cleaning and/or etching using alternate supply line configurations to shower head assembly 404.

The remote plasma source 426 may be a radio frequency or microwave plasma source adapted for chamber 402 cleaning and/or substrate 440 etching. Cleaning and/or etching gas may be supplied to the remote plasma source 426 via supply line 424 to produce plasma species which may be sent via conduit 429 and supply line 433 for dispersion through showerhead assembly 404 into chamber 402. Gases for a cleaning application may include fluorine, chlorine or other reactive elements.

In another embodiment, the gas delivery system 425 and remote plasma source 426 may be suitably adapted so that precursor gases may be supplied to the remote plasma source 426 to produce plasma species which may be sent through showerhead assembly 404 to deposit CVD layers, such as Group films, for example, on substrates 440. In general, a plasma, which is a state of matter, is created by the delivery of electrical energy or electromagnetic waves (e.g., radio frequency waves, microwaves) to a process gas (e.g., precursor gases) to cause it to at least partially breakdown to form plasma species, such as ions, electrons and neutral particles (e.g., radicals). In one example, a plasma is created in an internal region of the plasma source 426 by the delivery electromagnetic energy at frequencies less than about 100 gigahertz (GHz). In another example, the plasma source 426 is configured to deliver electromagnetic energy at a frequency between about 0.4 kilohertz (kHz) and about 200 megahertz (MHz), such as a frequency of about 162 megahertz (MHz), at a power level less than about 4 kilowatts (kW). It is believed that the formed plasma enhances the formation and activity of the precursor gas(es) so that the activated gases, which reach the surface of the substrate(s) during the deposition process can rapidly react to form a layer that has improved physical and electrical properties.

A purge gas (e.g., nitrogen) may be delivered into the chamber 402 from the showerhead assembly 404 and/or from inlet ports or tubes (not shown) disposed below the substrate carrier 414 and near the bottom of the chamber body 403. The purge gas enters the lower volume 410 of the chamber 402 and flows upwards past the substrate carrier 414 and exhaust ring 420 and into multiple exhaust ports 409 which are disposed around an annular exhaust channel 405. An exhaust conduit 406 connects the annular exhaust channel 405 to a vacuum system 412 which includes a vacuum pump (not shown). The chamber 402 pressure may be controlled using a valve system 407 which controls the rate at which the exhaust gases are drawn from the annular exhaust channel 405.

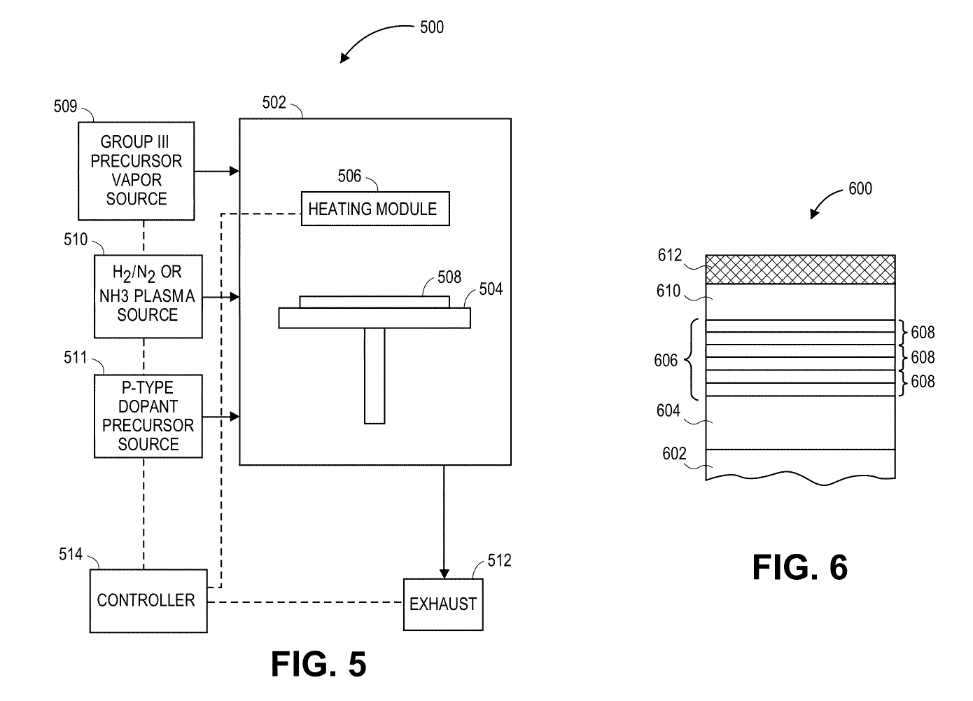

FIG. 5 illustrates a system suitable for use in fabricating a portion of an LED in conjunction with a degas process, in accordance with an embodiment of the present invention.

Referring to FIG. 5, the system 500 may include a deposition chamber 502 that includes a substrate support 504 and a heating module 506. The substrate support 504 may be adapted to support a substrate 508 during film formation within the chamber 502, and the heating module 506 may be adapted to heat the substrate 508 during film formation within the deposition chamber 502. More than one heating module, and/or other heating module locations may be used. The heating module 506 may include, for example, a lamp array or any other suitable heating source and/or element.

The system 500 may also include a group III, e.g., gallium, vapor source 509, a N₂/H₂ or NH₃ plasma source 510, and an exhaust system 512 coupled to the deposition chamber 502. The system 500 may also include a controller 514 coupled to the deposition chamber 502, the group III vapor source 509, the N₂/H₂ or NH₃ plasma source 510, and/or the exhaust system 512. The exhaust system 512 may include any suitable system for exhausting waste gasses, reaction products, or the like from the chamber 502, and may include one or more vacuum pumps. The N₂/H₂ or NH₃ plasma source 510 may be used for reaction with vapor for the group III vapor source 509. The N₂/H₂ or NH₃ plasma source 510 may be used to generate a plasma in the deposition chamber or remotely and introduced into the deposition chamber.

The controller 514 may include one or more microprocessors and/or microcontrollers, dedicated hardware, a combination the same, etc., that may be employed to control operation of the deposition chamber 502, the group III vapor source 509, the N₂/H₂ or NH₃ plasma source 510, and/or the exhaust system 512. In at least one embodiment, the controller 514 may be adapted to employ computer program code for controlling operation of the system 500. For example, the controller 514 may perform or otherwise initiate one or more of the operations of any of the methods/processes described herein, including the method described in association with Flowchart 300. Any computer program code that performs and/or initiates such operations may be embodied as a computer program product. Each computer program product described herein may be carried by a medium readable by a computer (e.g., a floppy disc, a compact disc, a DVD, a hard drive, a random access memory, etc.).

Group III precursor vapor may be created by placing an elemental group III species into a vessel, such as a crucible, and heating the vessel to melt the elemental group III species. The vessel may be heated to a temperature of from about 100 degrees Celsius to about 250 degrees Celsius. In some embodiments, nitrogen gas may be passed over the vessel containing the molten elemental group III species at a pressure of about 1 Torr and pumped to the process chamber. The nitrogen may be flowed at a rate of about 200 standard cubic centimeters per minute (sccm). The group III precursor vapor may be drawn into the process chamber by a vacuum. In an alternative embodiment, the substrate may be exposed to the group III precursor vapor, the N₂/H₂ or NH₃ based plasma and one or more of hydrogen and hydrogen chloride. The hydrogen and/or the hydrogen chloride may increase the rate of deposition. In another embodiment of the present invention, a group III-nitride film may be deposited on a substrate using a group III sesquichloride precursor and/or a group III hydride precursor.

It is to be understood that one or more of the above processes may be performed in a dedicated chamber within a cluster tool, or other tool with more than one chamber, e.g. an in-line tool arranged to have a dedicated chamber for fabricating layers of an LED. It is also to be understood that embodiments of the present invention need not be limited to the fabrication of LEDs. For example, in another embodiment, devices other than LED devices may be fabricated by an MOCVD process using a degas process, such as but not limited to field-effect transistor (FET) devices or power devices. In such embodiments, there may not be a need for a p-type material on top of a structure of layers. Instead, an n-type or un-doped material may be used in place of the p-type layer.

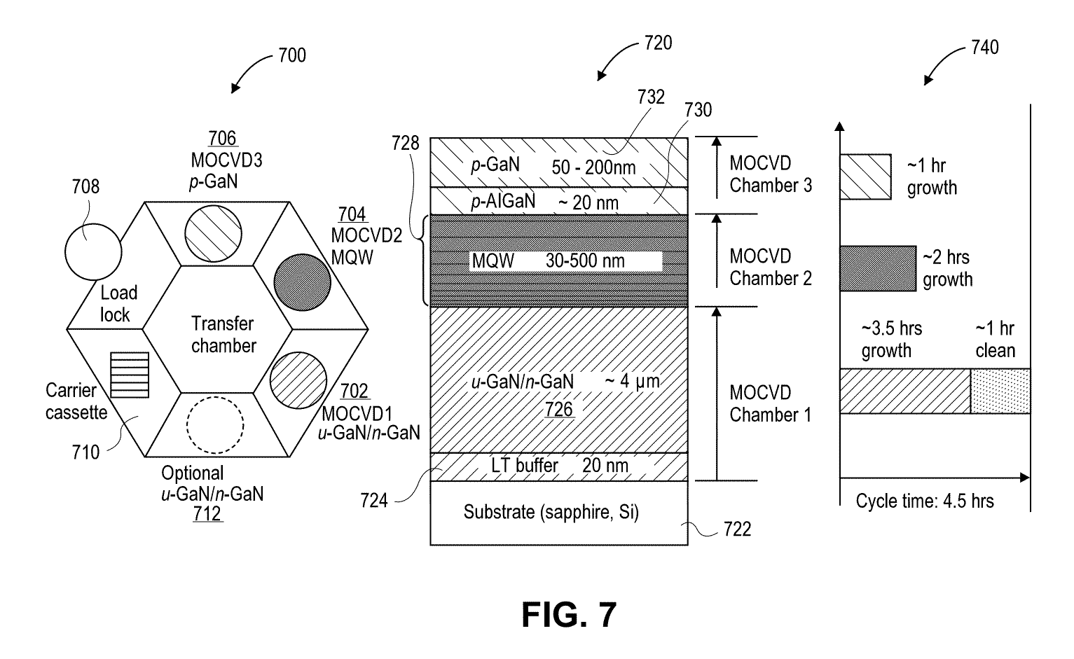

As an example of a multiple chamber system and process performed therein, FIG. 7 illustrates a cluster tool schematic, an LED structure, and a time-to-deposition plot, in accordance with one or more embodiments of the present invention.

Referring to FIG. 7, a cluster tool 700 includes an un-doped and/or n-type gallium nitride MOCVD reaction chamber 702 (MOCVD1: u-GaN/n-GaN), a multiple quantum well (MQW) MOCVD reaction chamber 704 (MOCVD2: MQW), and a p-type gallium nitride MOCVD reaction chamber 706 (MOCVD3: p-GaN). The cluster tool 700 may also include a load lock 708, a carrier cassette 710, and an optional additional un-doped and/or n-type gallium nitride MOCVD reaction chamber 712 for high volume applications, all of which are depicted in FIG. 7.

An LED structure 720 includes a stack of various material layers, many of which include III-V materials. For example, the LED structure 720 includes a silicon or sapphire substrate 722 (Substrate: sapphire, Si), a 20 nanometer thick buffer layer 724 (LT buffer), and an approximately 4 microns thick un-doped/n-type gallium nitride combination layer 726 (u-GaN/n-GaN). The buffer layer 724 may be a gallium nitride layer formed at relatively low processing temperatures. The buffer layer 724 and the un-doped/n-type gallium nitride combination layer 726 are formed in un-doped and/or n-type gallium nitride MOCVD reaction chamber 702 of cluster tool 700. The LED structure 720 also includes an MQW structure 728 with a thickness in the range of 30-500 nanometers. The MQW structure 728 is formed in MQW MOCVD reaction chamber 704 of cluster tool 700. The LED structure 720 also includes an approximately 20 nanometers thick p-type gallium aluminum nitride layer 730 (p-AlGaN) and a p-type gallium nitride layer 732 with a thickness in the range of 50-200 nanometers (p-GaN). The p-type gallium aluminum nitride layer 730 and the p-type gallium nitride layer 732 are formed in p-type gallium nitride MOCVD reaction chamber 706 of cluster tool 700.

A time-to-deposition plot 740 represents an example of chamber usage in cluster tool 700. The formation of the MQW structure 728 in MQW MOCVD reaction chamber 704 has a growth time of approximately 2 hours. And, the formation of the p-type gallium aluminum nitride layer 730 and the p-type gallium nitride layer 732 in p-type gallium nitride MOCVD reaction chamber 706 has a growth time of approximately 1 hour. Meanwhile, the formation of the buffer layer 724 and the un-doped/n-type gallium nitride combination layer 726 in un-doped and/or n-type gallium nitride MOCVD reaction chamber 702 has a growth time of approximately 3.5 hours. An additional approximately 1 hour may be required for chamber cleaning of chamber 702. Thus, overall, the cycle time for fabricating LED structure 720 in cluster tool 700 may be dictated by the cycle time of un-doped and/or n-type gallium nitride MOCVD reaction chamber 702, which is approximately 4.5 hours. It is to be understood that cleaning time may, but need not, include time for shut-down, plus clean time, plus recovery time. It is also to be understood that the above may represent an average since cleaning may not be performed between every chamber usage.

A timing sequence for LED material deposition specific to the formation of the buffer layer 724 and the un-doped/n-type gallium nitride combination layer 726 in un-doped and/or n-type gallium nitride MOCVD reaction chamber 702, as described in association with FIG. 7, is provided below. For example, the growth time of approximately 3.5 hours is broken into a 10 minute high temperature treatment of a sapphire substrate, a 5 minute low temperature formation of a buffer layer, a 10 minute buffer annealing operation, a 30 minute growth recovery operation, a 2 hour un-doped/n-type gallium nitride combination layer formation operation, and a 30 minute temperature ramp and stabilization operation (e.g., temp ramp 2-3° C./s).

It is to be understood that embodiments of the present invention are not limited to formation of layers on patterned sapphire substrates. Other embodiments may include the use of any suitable patterned single crystalline substrate upon which a group III-nitride epitaxial film may be formed. The patterned substrate may be formed from a substrate, such as but not limited to a sapphire (Al₂O₃) substrate, a silicon carbide (SiC) substrate, a silicon on diamond (SOD) substrate, a quartz (SiO₂) substrate, a glass substrate, a zinc oxide (ZnO) substrate, a magnesium oxide (MgO) substrate, and a lithium aluminum oxide (LiAlO₂) substrate. Any well know method, such as masking and etching may be utilized to form features, such as posts, from a planar substrate to create a patterned substrate. In a specific embodiment, however, the patterned substrate is a (0001) patterned sapphire substrate (PSS). Patterned sapphire substrates may be ideal for use in the manufacturing of LEDs because they increase the light extraction efficiency which is extremely useful in the fabrication of a new generation of solid state lighting devices. Other embodiments include the use of planar (non-patterned) substrates, such as a planar sapphire substrate. In other embodiments, the approaches herein are used to provide a group III-material layer directly on a silicon substrate.

In some embodiments, growth of a gallium nitride or related film on a substrate is performed along a (0001) Ga-polarity, N-polarity, or non-polar a-plane {112-0} or m-plane {101-0}, or semi-polar planes. In some embodiments, posts formed in a patterned growth substrate are round, triangular, hexagonal, rhombus shape, or other shapes effective for block-style growth. In an embodiment, the patterned substrate contains a plurality of features (e.g., posts) having a cone shape. In a particular embodiment, the feature has a conical portion and a base portion. In an embodiment of the present invention, the feature has a tip portion with a sharp point to prevent over growth. In an embodiment, the tip has an angle (\textcircled{˜}) of less than 145° and ideally less than 110° . Additionally, in an embodiment, the feature has a base portion which forms a substantially 90° angle with respect to the xy plane of the substrate. In an embodiment of the present invention, the feature has a height greater than one micron and ideally greater than 1.5 microns. In an embodiment, the feature has a diameter of approximately 3.0 microns. In an embodiment, the feature has a diameter height ratio of approximately less than 3 and ideally less than 2. In an embodiment, the features (e.g., posts) within a discrete block of features (e.g., within a block of posts) are spaced apart by a spacing of less than 1 micron and typically between 0.7 to 0.8 microns.

It is also to be understood that embodiments of the present invention need not be limited to n-GaN as a group III-V layer formed on a patterned substrate, such as described in association with FIG. 6. For example, other embodiments may include any group III-nitride epitaxial film that can be suitably deposited by MOCVD, or the like, in conjunction with a degas process. The group III-nitride film may be a binary, ternary, or quaternary compound semiconductor film formed from a group III element or elements selected from gallium, indium and aluminum and nitrogen. That is, the group III-nitride crystalline film can be any solid solution or alloy of one or more Group III element and nitrogen, such as but not limited to GaN, AlN, InN, AlGaN, InGaN, InAlN, and InGaAlN.

However, in a specific embodiment, the group III-nitride film is an n-type gallium nitride (GaN) film. The Group III-Nitride film can have a thickness between 2-500 microns and is typically formed between 2-15 microns. In an embodiment of the present invention, the group III-nitride film has a thickness of at least 3.0 microns to sufficiently suppress threading dislocations. Additionally, the group III-nitride film can be doped. The group III-nitride film can be p-typed doped using a p-type dopant such as but not limited Mg, Be, Ca, Sr, or any Group I or Group II element have two valence electrons. The group III-nitride film can be p-type doped to a conductivity level of between 1×10¹⁶ to 1×10²⁰ atoms/cm³. The group III-nitride film can be n-type doped using an n-type dopant such as but not limited to, Si, Ge, Sn, Pb, or a suitable Group IV, Group V, or Group VI element. The group III-nitride film can be n-type doped to a conductivity level of between 1×10¹⁶ to 1×10²⁰ atoms/cm³.

Thus, methods of fabricating light emitting diodes using a degas process have been disclosed. In accordance with an embodiment of the present invention, a method of fabricating a LED includes providing a partially formed group III-V material layer stack of the LED. The method also includes removing, by a degas process, contaminants from the partially formed group III-V material layer stack. The method also includes completing formation of the group III-V material layer stack of the LED. In one embodiment, providing the partially formed group III-V material layer stack of the LED includes providing an n-type gallium nitride (n-GaN) layer above a substrate, and completing formation of the group III-V material layer stack of the LED includes forming a multiple quantum well (MQW) above the n-GaN layer. In one embodiment, removing, by the degas process, contaminants from the partially formed group III-V material layer stack further includes removing contaminants from a carrier used to support a substrate having the partially formed group III-V material layer stack disposed there above. In one embodiment, removing, by the degas process, contaminants from the partially formed group III-V material layer stack enhances the photoluminescence (PL) of the LED.

What is claimed is:

1. A method of fabricating a light emitting diode (LED), the method comprising:
providing a partially formed group III-V material layer stack of the LED;
removing, by a degas process, contaminants from the partially formed group III-V material layer stack; and
completing formation of the group III-V material layer stack of the LED.

2. The method of claim 1, wherein providing the partially formed group III-V material layer stack of the LED comprises providing an n-type gallium nitride (n-GaN) layer above a substrate, and wherein completing formation of the group III-V material layer stack of the LED comprises forming a multiple quantum well (MQW) above the n-GaN layer.

3. The method of claim 2, wherein providing the n-GaN layer above the substrate comprises forming the n-GaN layer in the same process tool used to form the MQW, without removing the substrate from the process tool between forming the n-GaN layer and the MQW.

4. The method of claim 2, wherein providing the n-GaN layer above the substrate comprises introducing the n-GaN layer and substrate pairing into a process tool for forming the MQW.

5. The method of claim 1, wherein removing, by the degas process, contaminants from the partially formed group III-V material layer stack further comprises removing contaminants from a carrier used to support a substrate having the partially formed group III-V material layer stack disposed there above.

6. The method of claim 1, wherein removing, by the degas process, contaminants from the partially formed group III-V material layer stack enhances the photoluminescence (PL) of the LED.

7. A method of fabricating a light emitting diode (LED), the method comprising:
providing a substrate having an n-type gallium nitride (n-GaN) layer disposed there above; and
forming a multiple quantum well (MQW) above the n-GaN layer, the MQW comprising a plurality of bottom barrier layer and top well layer pairs, the bottom barrier layer of the first of the plurality of pairs formed on the n-GaN layer under degas conditions different from the conditions used to form the barrier layers of the other pairs of the plurality of pairs.

8. The method of claim 7, wherein at least a portion of the bottom barrier layer of the first of the plurality of pairs is formed at a temperature approximately in the range of 1000-1200 degrees Celsius, and wherein the barrier layers of the other pairs of the plurality of pairs are formed at a temperature of approximately 850 degrees Celsius.

9. The method of claim 8, wherein the entire bottom barrier layer of the first of the plurality of pairs is formed at a temperature approximately in the range of 1000-1200 degrees Celsius.

10. The method of claim 7, wherein providing the substrate having the n-GaN layer disposed there above comprises forming the n-GaN layer in the same process tool used to form the MQW, without removing the substrate from the process tool between forming the n-GaN layer and the MQW.

11. The method of claim 7, wherein providing the substrate having the n-GaN layer disposed there above comprises introducing the n-GaN layer and substrate pairing into a process tool for forming the MQW.

12. The method of claim 7, wherein the degas conditions are suitable to remove contaminants from the n-GaN layer or from a carrier used to support the substrate having the n-GaN layer disposed there above.

13. The method of claim 7, wherein the degas conditions are suitable to enhance the photoluminescence (PL) of the LED.

14. A method of fabricating a light emitting diode (LED), the method comprising:
providing a substrate having an n-type gallium nitride (n-GaN) layer disposed there above in a chamber having a first condition;
altering the condition of the chamber to a second condition different from the first condition to remove, by a degas process, contaminants from the n-GaN layer; and
forming a multiple quantum well (MQW) above the n-GaN layer, the MQW comprising a plurality of bottom barrier layer and top well layer pairs, the bottom barrier layer of the first of the plurality of pairs formed on the n-GaN layer formed under a third condition of the chamber, the third condition having a difference from the second condition greater than the difference from the first condition.

15. The method of claim 14, wherein the condition is temperature, the first condition is a temperature of approximately 300 degrees Celsius, the second condition is a temperature approximately in the range of 1000-1200 degrees Celsius, and the third condition is a temperature of approximately 850 degrees Celsius.

16. The method of claim 14, wherein the condition is pressure, and the first condition is a pressure of approximately 70 Torr, the second condition is a pressure less than 70 Torr, and the third condition is a pressure of approximately 100 Torr.

17. The method of claim 14, wherein providing the substrate having the n-GaN layer disposed there above comprises forming the n-GaN layer in the same process tool used to form the MQW, without removing the substrate from the process tool between forming the n-GaN layer and the MQW.

18. The method of claim 14, wherein providing the substrate having the n-GaN layer disposed there above comprises introducing the n-GaN layer and substrate pairing into a process tool for forming the MQW.

19. The method of claim 14, wherein removing, by the degas process, contaminants from the n-GaN layer further comprises removing contaminants from a carrier used to support the substrate having the n-GaN layer disposed there above.

20. The method of claim 14, wherein removing, by the degas process, contaminants from the n-GaN layer enhances the photoluminescence (PL) of the LED.
